(19) United States
(12) Patent Application Publication
(10) Pub. No.: US 2010/0319622 A1
(43) Pub. Date: Dec. 23, 2010

(54) FILM COATING APPARATUS FOR CHEMICAL VAPOR DEPOSITION AND PHYSICAL VAPOR DEPOSITION

(75) Inventor: SHAO-KAI PEI, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/541,697

(22) Filed: Aug. 14, 2009

(30) Foreign Application Priority Data
Jun. 18, 2009 (CN) 200910303414.0

(51) Int. Cl. C23C 16/00

(52) U.S. Cl. 118/728

(57) ABSTRACT

An exemplary film coating apparatus includes a housing, a holder for holding a workpiece, and a coating source. The housing defines a chamber therein. The holder and the coating source are received in the chamber. The coating source includes a supporting plate and a number of gas jetting heads. The supporting plate includes a first surface facing the holder, and defines a receiving recess at the first surface configured for receiving a target material, and a number of through holes. The gas jetting heads are capable of introducing one or more gases into the chamber, each gas jetting head passes through one respectively through hole and is fixed in the through hole.

### BACKGROUND

1. Technical Field

The present disclosure relates to film coating technology and, particularly, to a film coating apparatus capable of coating films using a selected one of a chemical vapor deposition method and a physical vapor deposition method.

2. Description of Related Art

Film coating methods include the chemical vapor deposition (CVD) method and the physical vapor deposition (PVD) method. A film coating apparatus usually can coat films using only one of the two methods. When both methods for coating films are needed, two separate film coating apparatuses have to be provided.

What is needed, therefore, is a film coating apparatus capable of coating films using both the CVD method and the PVD method.

### BRIEF DESCRIPTION OF THE DRAWINGS

Many aspects of the present film coating apparatus can be better understood with reference to the accompanying drawings. The components in the drawings are not necessarily drawn to scale, the emphasis instead being placed upon clearly illustrating the principles of the present film coating apparatus. In the drawings, all the views are schematic.

FIG. 1 is a cutaway view of a film coating apparatus according to an exemplary embodiment, the film coating apparatus including a coating source.

FIG. 2 is an isometric view of the coating source of FIG. 1, showing the coating source inverted.

FIG. 3 is an enlarged view of the coating source of FIG. 1.

### DETAILED DESCRIPTION

Embodiments of the present disclosure will now be described in detail below, with reference to the accompanying drawings.

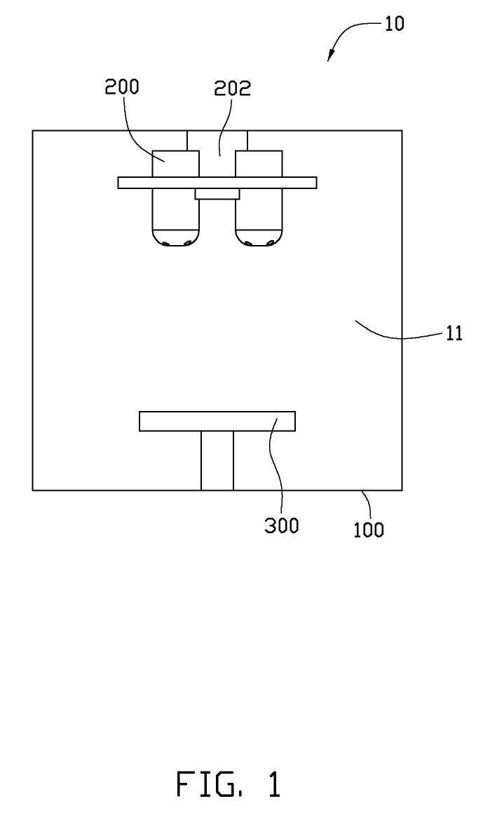

Referring to FIG. 1, a film coating apparatus 10, according to an exemplary embodiment, is shown. The film coating apparatus 10 includes a housing 100, a coating source 200, and a holder 300.

The housing 10 defines a chamber 11 therein. The coating source 200 and the holder 300 are received in the chamber 11. The holder 300 is configured for holding a workpiece such as a substrate (not shown) to be coated with a film or films.

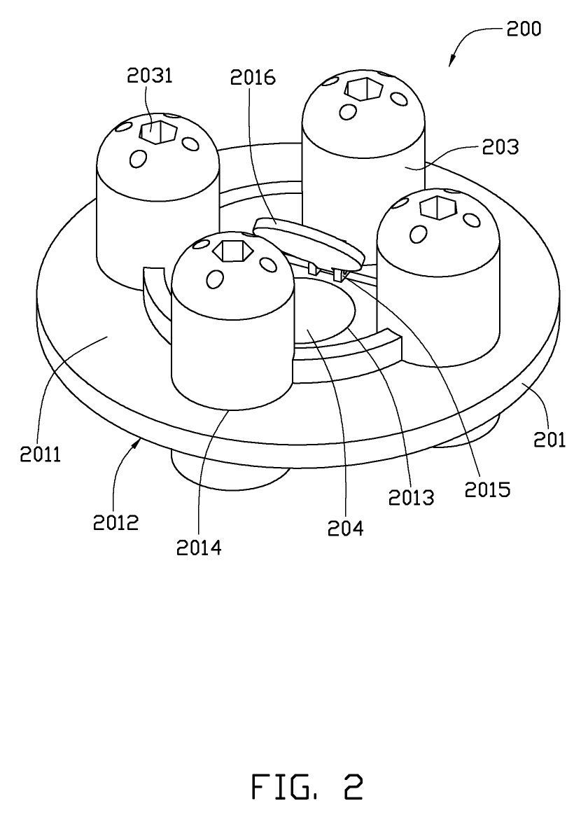

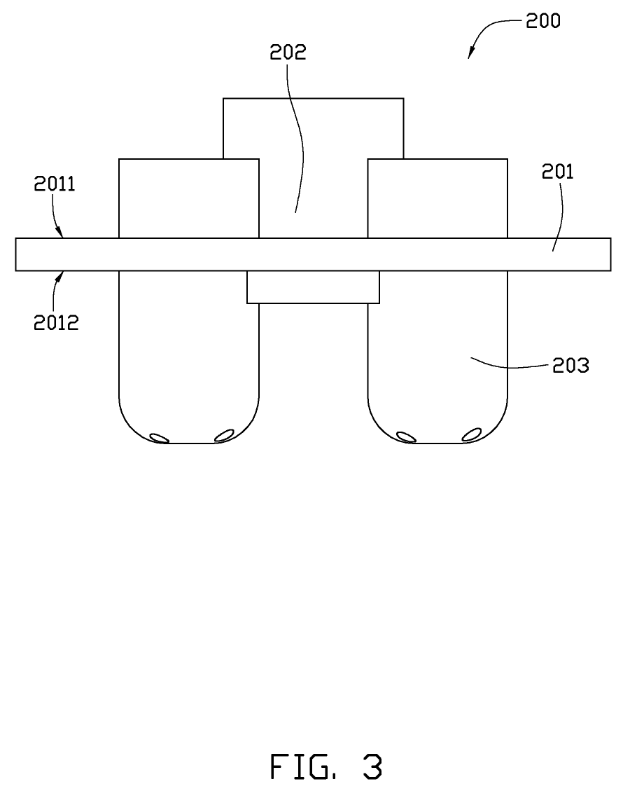

Referring also to FIG. 2 and FIG. 3, the coating source 200 includes a supporting plate 201, a rotating shaft 202, a number of gas jetting heads 203, and a target material 204.

In the present embodiment, the supporting plate 201 is disk-shaped. The supporting plate 201 includes a bottom first surface 2011 facing the holder 300 and a top second surface 2012. The supporting plate 201 defines a receiving recess 2013 in the center of the first surface 2011, and a number of through holes 2014 surrounding the receiving recess 2013. The receiving recess 2013 is for receiving the target material 204, which is utilized in a film coating process using a PVD method. The supporting plate 201 further includes a cover 2016 for covering the receiving recess 2013 and thereby preventing the target material 204 from being contaminated during a film coating process using a CVD method. The cover 2016 is pivotably connected to a connecting portion 2015, which is fixed on the first surface 2011 of the supporting plate 201. In the present embodiment, the connecting portion 2015 is a hinge.

The rotating shaft 202 is fixed to the second surface 2012 of the supporting plate 201. The rotating shaft 202 can support and rotate the supporting plate 201. The rotating shaft 202 can be rotated by a motor (not shown).

In the present embodiment, the coating source 200 includes four gas jetting heads 203, and the supporting plate 201 defines four through holes 2014 corresponding to the four gas jetting heads 203. Each gas jetting head 203 passes through the corresponding through hole 2014 and is fixed in the corresponding through hole 2014. Each gas jetting head 203 includes a number of gas openings 2031. In the illustrated embodiment, each gas jetting head 203 has five gas openings 2031. A top end of the gas jetting head 203 can be connected to one or more types of gas sources (not shown), as desired. In such case, the gas openings 2031 function as gas inlets of the chamber 11. The top end of the gas jetting head 203 can also be connected to a vacuum pump (not shown), as desired. In such case, the gas openings 2031 function as gas outlets of the chamber 11 for vacuumizing the chamber 11 of the housing 10.

During a film coating process using a CVD method, the target material 204 can be covered with the cover 2014, and reaction gases can flow into the chamber 11 from the gas openings 2031 of the gas jetting heads 203. During a film coating process using a PVD method, the chamber 11 can be vacuumized by the vacuum pump via the gas openings 2031 of the gas jetting heads 203. Then an inert gas, such as argon or krypton, can be introduced into the chamber 11 from the gas openings 2031 of the gas jetting heads 203.

While certain embodiments have been described and exemplified above, various other embodiments will be apparent to those skilled in the art from the foregoing disclosure. The invention is not limited to the particular embodiments described and exemplified, and the embodiments are capable of considerable variation and modification without departure from the scope and spirit of the appended claims.

What is claimed is:

1. A film coating apparatus comprising:
a housing defining a chamber therein;
a holder received in the chamber, the holder capable of holding a workpiece; and
a coating source received in the chamber, the coating source comprising:
a supporting plate comprising a first surface facing the holder, the supporting plate defining a receiving recess at the first surface configured for receiving a target material, and one or more through holes; and
one or more gas jetting heads capable of introducing one or more gases into the chamber, each gas jetting head passing through one respective through hole and being fixed in the through hole.

2. The film coating apparatus of claim 1, wherein the receiving recess is at the center of the first surface.

3. The film coating apparatus of claim 2, wherein the one or more through holes are a plurality of through holes, which surrounding the receiving recess.

4. The film coating apparatus of claim 1, wherein the supporting plate comprises a cover for covering the receiving recess to prevent the target material from being polluted.

5. The film coating apparatus of claim 4, wherein the cover is pivotably connected to a connecting portion fixed on the first surface of the supporting plate.

6. The film coating apparatus of claim 1, wherein the supporting plate further comprises a second surface, which is at an opposite side of the supporting plate to the first surface, and the coating source further comprises a rotating shaft fixed to the supporting plate at the second surface.

7. The film coating apparatus of claim 1, wherein said one or more gas jetting heads are capable of being connected to a vacuum pump for vacuumizing the chamber of the housing.

8. A film coating apparatus comprising:
a housing defining a chamber therein;
a holder received in the chamber, the holder configured for holding a workpiece; and
a coating source received in the chamber, the coating source comprising:
a supporting plate comprising a first surface facing the holder, the supporting plate defining a receiving recess at the first surface, and one or more through holes;
one or more gas jetting heads capable of introducing gases into the chamber, each gas jetting head passing through one respective through hole and being fixed in the through hole; and
a target material received in the receiving recess.

9. The film coating apparatus of claim 8, wherein the receiving recess is at the center of the first surface.

10. The film coating apparatus of claim 9, wherein the one or more through holes are a plurality of through holes, which surrounding the receiving recess.

11. The film coating apparatus of claim 8, wherein the supporting plate comprises a cover for covering the receiving recess to prevent the target material from being contaminated.

12. The film coating apparatus of claim 11, wherein the cover is pivotably connected to a connecting portion fixed on the first surface of the supporting plate.

13. The film coating apparatus of claim 8, wherein the supporting plate further comprises a second surface, which is at an opposite side of the supporting plate to the first surface, and the coating source further comprises a rotating shaft fixed to the supporting plate at the second surface.

14. The film coating apparatus of claim 8, wherein said one or more gas jetting heads are capable of being connected to a vacuum pump for vacuumizing the chamber of the housing.

15. A film coating apparatus comprising:
a housing defining a chamber therein;
a holder received in the chamber, the holder capable of holding a workpiece; and
a coating source received in the chamber, the coating source comprising:
a supporting plate comprising a first surface facing the holder, the supporting plate defining a receiving recess at the first surface configured for receiving a target material; and
one or more gas jetting heads fixed in the supporting plate and capable of introducing one or more gases into the chamber at a side of the supporting plate corresponding to the first surface.
